(19) United States
(12) Patent Application Publication
(10) Pub. No.: US 2026/0050219 A1
(43) Pub. Date: Feb. 19, 2026

(54) METHOD FOR PRODUCING PHENOLIC HYDROXYL GROUP-CONTAINING BRANCHED ORGANOPOLYSILOXANE

(71) Applicant: DOW TORAY CO., LTD., Shinagawa-Ku, Tokyo (JP)

(72) Inventors: Wenbin LIANG, Ichihara-shi, Chiba (JP); Takuya OGAWA, Ichihara-shi, Chiba (JP)

(21) Appl. No.: 19/102,297

(22) PCT Filed: Jul. 25, 2023
(86) PCT No.: PCT/JP2023/027141

§ 371 Date: Feb. 7, 2025

(30) Foreign Application Priority Data
Aug. 8, 2022 (JP) 2022-126482

(51) Int. Cl. G03F 7/075; C08G 77/00; C08G 77/04

(52) U.S. Cl. CPC G03F 7/0757; C08G 77/045; C08G 77/80

(57) ABSTRACT

Provided is a method for producing a curable reactive organopolysiloxane that has favorable alkali solubility and curability (particularly high energy beam curability). Specifically, provided is a method of producing a phenolic hydroxyl group-containing branched organopolysiloxane having at least a step of performing a hydrosilylation reaction of a branched organopolysiloxane expressed by the following average unit formula (1′): (D₃SiO_{1/2})ₐ(D₂SiO_{2/2})_{b}(RSiO_{3/2})_{c}(SiO_{4/2})_{d} (1′) wherein R is a monovalent hydrocarbon group or the like, each D is independently the same group as R, at least one of all Ds is a hydrogen atom, and a, b, c, and d are numbers that satisfy the following conditions: 0≤a, 0≤b, 0<(a+b), and 0<(c+d). The method may further include a step of introducing a carboxylic acid-containing organic group into the molecule by reacting the phenolic hydroxyl group-containing organic group with an acid anhydride.

### TECHNICAL FIELD

The present invention relates to a method for producing an alkali soluble phenolic hydroxyl group-containing branched organopolysiloxane which can be cured by actinic rays, for example high energy beams or electron beams. The phenolic hydroxyl group-containing branched organopolysiloxane produced by the present invention has high solubility in alkaline aqueous solutions and favorable high energy beam curability, and therefore exhibits excellent lithography performance and is suitable as a resist material or insulating material for electronic and electric devices that require patterning, and in particular as a material for use as a coating agent.

### BACKGROUND ART

Due to high heat resistance and excellent chemical stability, silicone resins have been used as coating agents, potting agents, insulating materials, and the like for electronic and electrical devices. Among silicone resins, high energy beam curable silicone compositions have also been reported.

Touch panels are used in various display devices such as mobile devices, industrial equipment, car navigation systems, and the like. In order to improve detection sensitivity, electrical influence from light emitting sites such as light-emitting diodes (LED), organic EL devices (OLED), and the like must be suppressed, and an insulating layer is usually placed between the light-emitting part and the touchscreen. On the other hand, thin display devices such as OLEDs and the like have a structure in which a plurality of functional thin layers are stacked. In recent years, studies have been conducted to improve the visibility of display devices by laminating insulating layers formed from acrylate polymer with a high refractive index and multifunctional polymerizable monomers, above and below the touchscreen layer. (For example, see Patent Documents 1 and 2)

Advances in photolithography technology have enabled achieving finer patterns in the manufacture of semiconductor devices, and the progress has been remarkable in recent years. The technique for achieving this miniaturization generally involves using light sources with shorter wavelengths, and resist materials using electron beams and extreme ultraviolet (EUV) rays are being investigated for use in regions with a resolution of 20 nm or less. With technology using EUV, excitation of the resist material itself by irradiation is important, and polymers having phenol groups are being actively studied as EUV resist materials. Patent Document 3 discloses a resist composition that contains an acrylic polymer having a phenol group and a specific acid generating agent and has favorable stability over time.

Similarly, silicone-based resist materials are also being considered, taking advantage of their excellent etching resistance. Patent Document 4 discloses a resist composition containing a phenol-functional polysiloxane which is a reaction product of a hydrogen-functional polysiloxane, an alkenyl-functional polysiloxane, and a specific diallyl compound. However, since linear polysiloxane components are abundant, the product does not exhibit alkali solubility. Furthermore, Patent Documents 5 and 6 disclose phenol-functional polysilsesquioxanes having a specific structure and resist compositions. These are alkali soluble, but there are problems with solubility. Furthermore, Patent Document 7 discloses a photosensitive resin composition containing a mixture of a polysiloxane having an acetal-protected phenolic hydroxyl group and a polysiloxane having a cationically curable group and a phenolic hydroxyl group. The composition described therein is also alkali soluble, but no consideration has been given to polysiloxanes that do not contain cationic curable groups and contain only phenolic hydroxyl groups.

In other words, although phenol-functional polysiloxanes and high energy beam-curable compositions containing these have been disclosed, it is difficult to say that a curable organopolysiloxane in which the polysiloxane itself has high solubility in an aqueous alkaline solution and exhibits excellent high energy beam curability, and a method for producing the same have been sufficiently disclosed.

### RELATED ART DOCUMENTS

### Patent Documents

Patent Document 1: Japanese Unexamined Patent Application 2013-140229
Patent Document 2: Japanese Unexamined Patent Application 2021-61056
Patent Document 3: Japanese Unexamined Patent Application 2017-227733
Patent Document 4: Japanese Unexamined Patent Application 2004-262952
Patent Document 5: Japanese Unexamined Patent Application 2016-212350
Patent Document 6: Japanese Unexamined Patent Application 2005-283991
Patent Document 7: WO2016-52391

### SUMMARY OF THE INVENTION

### Problem to be Solved by the Invention

As described above, there remains a need for a method for producing curable reactive organopolysiloxanes that have good alkali solubility and curability (particularly high energy beam curability).

### Means for Solving the Problem

The present invention was made to achieve the aforementioned object, and was completed based on a discovery that an organopolysiloxane having a specific branched structure with a phenolic hydroxyl group-containing organic group on a silicon atom and optionally a carboxylic acid-containing organic group can be simply produced by a process including a hydrosilylation reaction using an organopolysiloxane having a specific branched structure as a starting raw material.

In particular, the present invention relates to a method for producing a phenolic hydroxyl group-containing branched organopolysiloxane that has high solubility in aqueous alkaline solutions and favorable curability. Note that the method for curing the branched organopolysiloxane produced by the present invention is not limited to high energy beam irradiation, and any method that can cause a curing reaction of the high energy beam-curable functional group can be used. For example, curing can be achieved by electron beam irradiation.

Specifically, the production method according to the present invention is a method for producing a phenolic hydroxyl group-containing branched organopolysiloxane expressed by the following average unit formula (1), which includes a step of subjecting a branched organopolysiloxane expressed by the following average unit formula (1′) to a hydrosilylation reaction.

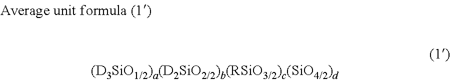

(In the formula, R is a group selected from hydrogen atoms, unsubstituted or fluorine-substituted monovalent hydrocarbon groups, alkoxy groups, and hydroxyl groups; each D is independently a group similar to R; at least one of all Ds is a hydrogen atom; and a, b, c, and d are numbers that satisfy the following conditions: 0≤a, 0≤b, 0<(a+b), and 0<(c+d).)

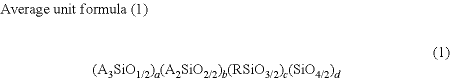

{In the formula, R represents the same groups as described above;
each A independently represents the same groups as R,
groups M¹ expressed by the following formula (21):

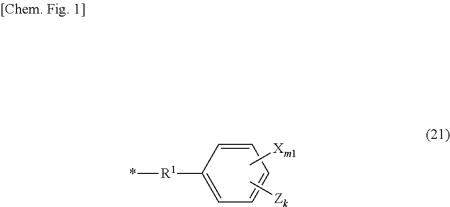

(where R¹ is a divalent hydrocarbon group having 2 to 6 carbon atoms, X is a hydroxyl group, Z is a monovalent group expressed by —OR³ (where R³ is an acid-dissociable group),
m1 is a number in a range of 1 to 3, k is a number in a range of 0 to 3, and * is a silicon atom-bonding site on the organopolysiloxane),
groups M² expressed by the following formula (22):

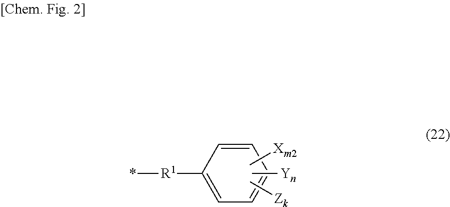

(In the formula, R¹, X, and Z are the same groups as described above,
Y is a monovalent hydrophilic group expressed by —Wₚ—R²_{q}—CO₂H (where W represents a divalent linking group selected from O(C═O), NR⁵(C═O), and S(C═O) groups, p is 0 or 1,
q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group),
m2 is 0 or 1, n is a number in a range of 1 to 3, k is a number in a range of 0 to 3, and * is a silicon atom-bonding site on the organopolysiloxane),
groups J expressed by the following formula (3):

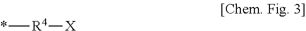

(in the formula, R⁴ represents a divalent hydrocarbon group with 2 to 6 carbon atoms, and X represents the aforementioned groups); and
groups L expressed by the following formula (4):

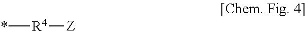

(in the formula, R⁴ and Z represents the same groups as described above); and
at least one of all A represents M¹, and a, b, c, and d are numbers satisfying the aforementioned conditions.

The production method of the present invention includes at least step (I) of performing a hydrosilyl reaction between a silicon atom-bonded hydrogen atom-containing branched organopolysiloxane expressed by the above average unit formula (1′) with an unsaturated hydrocarbon group-containing compound expressed by the following formula (33):

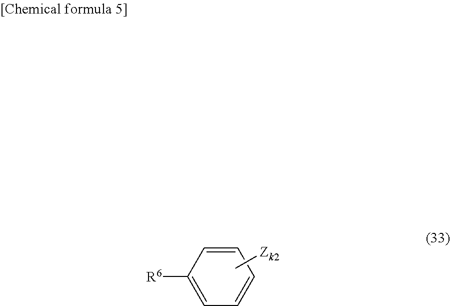

(In the formula, R⁶ is a monovalent unsaturated hydrocarbon group having 2 to 6 carbon atoms, Z is the same groups as described above, and k2 is a number ranging from 1 to 3.)

After the aforementioned step (I), the production method of the present invention may include step (II) where one or more acidic substance is reacted with the product of step (I), a compound expressed by the following formula (34):

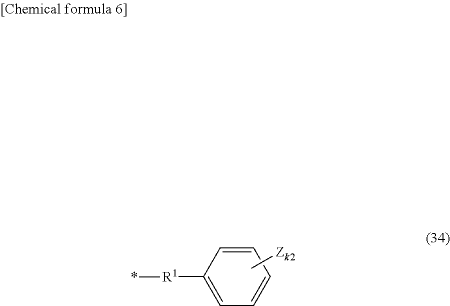

(In the formula, R¹ is a divalent hydrocarbon group having 2 to 6 carbon atoms, Z is the same group as defined above, k2 is the same number as defined above, and * is a bonding site to a silicon atom on the organopolysiloxane.)
to convert at least a portion of the groups Z to hydroxyl groups (X), thereby converting the functional group expressed by formula (34) to the group M¹ expressed by formula (21).

Furthermore, after step (II), the production method of the present invention may further include step (III), in which the branched organopolysiloxane having group M¹ expressed by formula (21) in the molecule obtained in step (II) is reacted with one or more types of acid anhydride to convert a portion of group M¹ to group M² expressed by formula (22).

In the production method of the present invention, the silicon atom-bonded hydrogen atom-containing branched organopolysiloxane expressed by the aforementioned average unit formula (1′) may have 50 or fewer silicon atoms in the molecule, and may have 5 to 20 silicon atoms in the molecule.

In the production method of the present invention, the variable “a” in the average unit formula (1′) may be a number of 1 or more, and a, b, c, and d may further be numbers that satisfy the following condition: 0.5≤a/(b+c+d)≤2.0.

In the production method of the present invention, the silicon atom-bonded hydrogen atom-containing branched organopolysiloxane expressed by the average unit formula (1′) may be an organopolysiloxane expressed by:

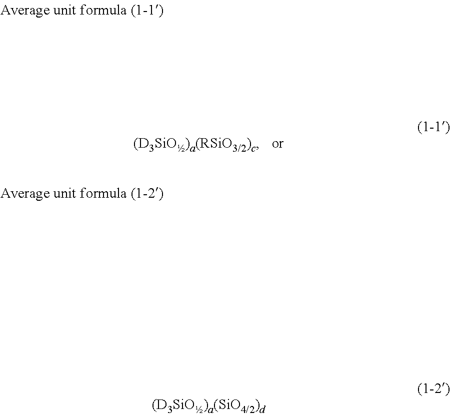

(In these formulas, R and A are the same groups as defined above, and a, c, and d are numbers satisfying the above conditions.)

### Effect of the Invention

The present invention provides a method for producing a phenolic hydroxyl group-containing branched organopolysiloxane that has favorable coatability on a substrate and demonstrates high solubility in an aqueous alkaline solution normally used in the development process performed to form a pattern of a desired shape. Therefore, unreacted and uncured organopolysiloxane and curable compositions containing this organopolysiloxane can be easily removed by a washing operation using an alkaline aqueous solution during the development process that accompanies selective high energy beam irradiation, enabling high-precision patterning with a simple process. In particular, the cured product formed from the phenolic hydroxyl group-containing branched organopolysiloxane obtained by the production method of the present invention has an advantage of being optically transparent with hardness and the like that can be designed within a wide range, enabling use as a resist material that utilizes a short wavelength light source, especially EUV. Furthermore, the compound is useful as a material for an insulating layer for electronic devices, particularly for thin display devices such as OLEDs, particularly as a patterning material and a coating material.

### DESCRIPTION OF THE PREFERRED EMBODIMENTS

The production method of the present invention will be further described below in detail.

The branched organopolysiloxane obtained by the production method of the present invention can have at least one phenolic hydroxyl group and optionally one carboxyl group. Thereby, the polysiloxane is highly soluble in aqueous alkaline solutions commonly used as photolithography developers in the semiconductor industry.

Alkali solubility means that the formed coating film is soluble in the alkaline solution normally used in the development process to form a pattern of a desired shape. Well-known alkaline aqueous solutions include basic aqueous solutions of sodium hydroxide (NaOH), potassium hydroxide (KOH), quaternary ammonium salts, and the like, but aqueous solutions of KOH and tetramethylammonium hydroxide (TMAH) are typically used, and TMAH aqueous solutions are particularly widely used. In the present invention, this means that the material is soluble in an aqueous alkaline solution.

More specifically, “soluble in an aqueous alkaline solution” means that if the branched organopolysiloxane of the present invention is applied to a glass plate to a thickness of 0.5 μm, after which the coating film is immersed in a 2.38% aqueous solution of TMAH for 1 minute and then washed with water, the coating film made of the organopolysiloxane has a mass reduction rate of 90 mass % or more. In particular, if the coating film made of the organopolysiloxane has a mass reduction rate of 95 mass % or more, or 98 mass % or more when evaluated by the aforementioned method, the coating film can be considered to have particularly excellent solubility in an aqueous alkaline solution. Note that spin-coating or other methods are commonly used to apply the organopolysiloxane on a glass plate. If the coating is applied using an organic solvent, as described below, the organic solvent must be removed in advance by drying or other means. Furthermore, if the composition is mainly composed of organopolysiloxane, the solubility of the high energy beam-curable composition containing the organopolysiloxane of the present invention can be evaluated in an aqueous alkaline solution by the aforementioned method. Furthermore, the water washing process is generally performed by immersion in a water bath at about room temperature (25° C.) or by running water at about the speed of domestic tap water for 10 to 15 seconds, so as not to adversely affect the formed patterning or the substrate.

Note that the branched siloxane obtained by the production method of the present invention includes one or more type selected from the aforementioned repeating units of (A₃SiO_{1/2}) and (A₂SiO_{2/2}) and thus tends to be more soluble in aqueous alkaline solutions compared to organopolysiloxanes containing only silsesquioxane units, so there is a tendency to produce organopolysiloxane with particularly excellent alkali solubility where the mass loss rate of the coating film is 90% or more, preferably 98% or more, when the solubility in an aqueous alkaline solution of a coating film containing branched organopolysiloxane including these siloxane units is evaluated by the method described above.

The method for producing the phenolic hydroxyl group-containing branched organopolysiloxane of the present invention expressed by following average unit formula (1) includes at least a step of performing a hydrosilylation reaction of a silicon atom-bonded hydrogen atom-containing branched organopolysiloxane expressed by the following average unit formula (1′):

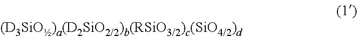

(In the formula, R is a group selected from a hydrogen atom, an unsubstituted or fluorine-substituted monovalent hydrocarbon group, an alkoxy group, and a hydroxyl group; each D is independently a group similar to R; at least one of all Ds is a hydrogen atom; and a, b, c, and d are numbers that satisfy the following conditions: 0≤a, 0≤b, 0<(a+b), and 0<(c+d).)

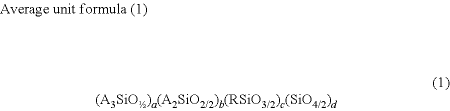

{In the formula, R represents the same groups as described above;
each A independently represents the same groups as R,
groups M¹ expressed by the following formula (21):

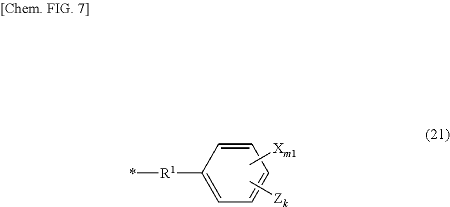

(where R¹ is a divalent hydrocarbon group having 2 to 6 carbon atoms, X is a hydroxyl group, Z is a monovalent group expressed by —OR³ (where R³ is an acid-dissociable group),
m1 is a number in a range of 1 to 3, k is a number in a range of 0 to 3, and * is a silicon atom-bonding site on the organopolysiloxane), and
a monovalent hydrocarbon group expressed by the following formula (22):

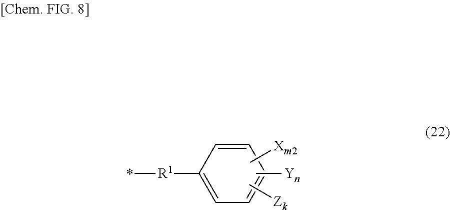

(In the formula, R¹, X, and Z are the same groups as described above,
Y is a monovalent hydrophilic group expressed by —Wₚ—R²_{q}—CO₂H (where W represents a divalent linking group selected from O(C═O), NR⁵(C═O), and S(C═O) groups, p is 0 or 1,
q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group),
m2 is 0 or 1, n is a number in a range of 1 to 3, k is a number in a range of 0 to 3, and * is a silicon atom-bonding site on the organopolysiloxane)

In the silicon-bonded hydrogen atom-containing branched organopolysiloxane expressed by the average unit formula (1′), R in the formula is a group selected from hydrogen atoms, unsubstituted or fluorine-substituted monovalent hydrocarbon groups, alkoxy groups, and hydroxyl groups. The unsubstituted or fluorine-substituted monovalent hydrocarbon group is preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups, but 3,3,3-trifluoropropyl groups are preferable. Examples of the alkoxy groups include methoxy groups, ethoxy groups, propoxy groups, and isopropoxy groups.

In the silicon-bonded hydrogen atom-containing branched organopolysiloxane expressed by the average unit formula (1′), the functional groups D in the formula may each independently be the same group as R, but at least one of all Ds is a hydrogen atom. The phenolic hydroxyl group-containing organic group represented by group M¹, a precursor functional group thereof, or a carboxylic acid-containing organic group represented by group M² obtained by reacting the phenolic hydroxyl group-containing organic group with an acid anhydride is introduced at the hydrogen atom of group D by a hydrosilylation reaction described later. In other words, the number of each of the modifying groups in the final phenolic hydroxyl group-containing branched organopolysiloxane is determined by the functional group D, which is a hydrogen atom in the silicon-bonded hydrogen atom-containing branched organopolysiloxane expressed by the average unit formula (1′).

The group D other than a hydrogen atom or a hydroxyl group is preferably a group selected from unsubstituted or fluorine-substituted alkyl groups, cycloalkyl groups, arylalkyl groups, aryl groups, and alkoxy groups having 1 to 20 carbon atoms. Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups, but 3,3,3-trifluoropropyl groups are preferable. Examples of the alkoxy groups include methoxy groups, ethoxy groups, propoxy groups, and isopropoxy groups.

The silicon atom-bonded hydrogen atom-containing branched organopolysiloxane expressed by the average unit formula (1′) above preferably has 50 or fewer silicon atoms, more preferably 20 or fewer silicon atoms, and particularly preferably in the range of 3 to 50, and particularly preferably in the range of 5 to 20 silicon atoms. Fewer silicon atoms leads to a narrower composition distribution and molecular weight distribution of the branched organopolysiloxane. Therefore, as long as the number of silicon atoms is within this range, the phenolic hydroxyl group-containing branched organopolysiloxane obtained by the production method of the present invention using this branched organopolysiloxane as a starting raw material will have reduced overall viscosity of the curable composition and improved coatability and lithography properties.

There are no significant limitations on the ratio of each constituent unit in the silicon atom-bonded hydrogen atom-containing branched organopolysiloxane expressed by the aforementioned average unit formula (1), but at least one of a and b is not zero. Similarly, at least one of c and d is not 0. Therefore, a, b, c, and d are numbers that satisfy the following conditions: 0≤a, 0≤b, 0<(a+b), and 0<(c+d).

As described above, a modifying group such as a phenolic hydroxyl group-containing organic group represented by group M¹, a precursor functional group thereof, or a carboxylic acid-containing organic group represented by group M² obtained by reacting the phenolic hydroxyl group-containing organic group with an acid anhydride is introduced at functional group D, which is a hydrogen atom on the silicon atom-bonded hydrogen atom-containing branched organopolysiloxane. Therefore, the high-energy beam curability, alkali solubility, and surface tack after application to a base material of the finally obtained phenolic hydroxyl group-containing branched organopolysiloxane can be appropriately controlled by setting the values of a, b, c, and d of the silicon atom-bonded hydrogen atom-containing branched organopolysiloxane, as the raw material, within appropriate ranges. However, in order to maintain a favorable balance between these characteristics, the values of a, b, c, and d are preferably set so as to satisfy the following formula:

$$0.5 \leq a / ( b + c + d ) \leq 2.0$$

Here, b is the number of (D₂SiO_{2/2}) units, but b=0 is also possible. In this case, at least one D in the (D₃SiO_{1/2}) unit in the molecule is a hydrogen atom.

Furthermore, the preferable ranges of the ratios a/c and a/d of the siloxane units constituting the silicon atom-bonded hydrogen atom-containing branched organopolysiloxane can be expressed by the aforementioned relational expression 0.5≤a/(b+c+d)≤2.0. In other words, 0.5≤a/c≤2.0 and 0.5≤a/d≤2.0. Within these ranges, the aforementioned properties of the finally obtained phenolic hydroxyl group-containing branched organopolysiloxane, namely, high energy beam curability, alkali solubility, and surface tackiness after application to a base material can be appropriately controlled.

A specific example of the silicon atom-bonded hydrogen atom-containing branched organopolysiloxane that is preferably used in the present invention preferably contains monoorganosiloxy units (D₃SiO_{1/2}). In particular, the polymer may have one or more structures selected from the following average unit formulas (1-1′) and (1-2′). In other words, b in the aforementioned average unit formula (1′) is preferably 0.

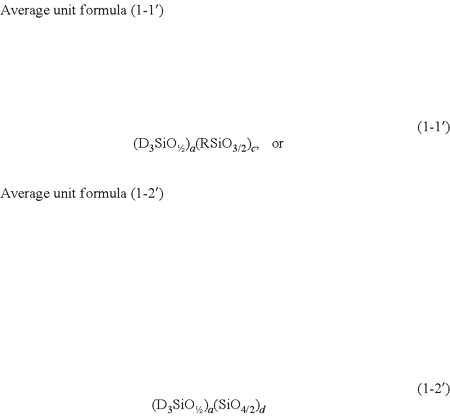

(In these formulas, R and A are the same groups as defined above, and a, c, and d are numbers satisfying the above conditions.)

More specific structures of the silicon-bonded hydrogen atom-containing branched organopolysiloxane include polysiloxanes composed of the following structural units: Here, M represents (Me₃SiO_{1/2}), D represents (Me₂SiO_{2/2}), T represents (MeSiO_{3/2}), Q represents (SiO_{4/2}), D^{Ph} represents (MePhSiO_{2/2}), D^{Ph2} represents (Ph₂SiO_{2/2}), T^{Ph} represents (PhSiO_{3/2}), M^{H} represents (Me₂HSiO_{1/2}), D_{H} represents (MeHSiO_{2/2}), T^{H} represents (HSiO_{3/2}), Me represents a methyl group, and Ph represents a phenyl group.

MM^{H}Q, M^{H}Q, M^{H}DQ, M^{H}TQ, MD^{H}Q, MDD^{H}Q, M^{H}D^{H}Q, MD^{H}TQ, M^{H}T^{H}Q, M^{H}T^{Ph}, MM^{H}T^{Ph}, M^{H}DT^{Ph}, M^{H}D^{Ph}T^{Ph}, M^{H}D^{H}T^{Ph}, M^{H}T^{Ph}Q, M^{H}TT^{Ph}, M^{H}DTT^{Ph}, M^{H}D^{Ph2}T, M^{H}DD^{Ph2}T Of these, MM^{H}Q, M^{H}Q, M^{H}T^{Ph}, MM^{H}T^{Ph}, M^{H}DTT^{Ph} and M^{H}T^{Ph}Q are exemplified as preferred branched organopolysiloxanes, with MM^{H}Q and M^{H}T^{Ph} being particularly preferred branched organopolysiloxanes.

There are no particular limitations on the molecular weight of the silicon-bonded hydrogen atom-containing branched organopolysiloxane, but taking into consideration the properties and molecular weight of the final phenolic hydroxyl group-containing branched organopolysiloxane, the weight average molecular weight, based on a polystyrene standard, as measured by gel permeation chromatography is preferably in a range of 500 to 2,000, more preferably 800 to 1,500.

### [Step (I)]

Preferably, the production method according to the present invention includes the step of subjecting the above-mentioned silicon-bonded hydrogen atom-containing branched organopolysiloxane to a hydrosilylation reaction with a phenol derivative having a monovalent unsaturated hydrocarbon group to provide a phenolic hydroxyl group-containing organic group represented by group M¹ or a precursor functional group thereof.

In step (I), the compound to be subjected to the hydrosilylation reaction with the silicon-bonded hydrogen atom-containing branched organopolysiloxane is preferably a phenol derivative having a monovalent unsaturated hydrocarbon group. Here, the compound can be subjected to the hydrosilylation reaction as is, or can be used after protecting the phenol group with an acid-dissociable group or the like. In the present invention, a phenol group protected with an acid-dissociable group or the like is preferably subjected to the hydrosilylation reaction, from the perspective of suppressing side reactions. Specifically, an unsaturated hydrocarbon group-containing compound represented by the following formula (33) is preferably used.

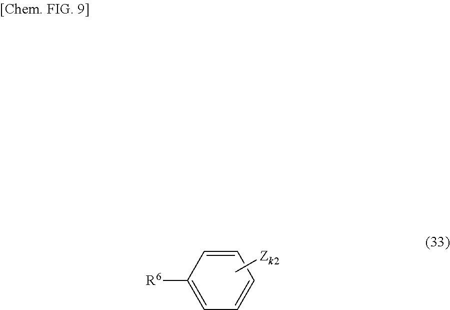

(where R⁶ is a monovalent unsaturated hydrocarbon group having 2 to 6 carbon atoms, Z is a monovalent group expressed by —OR³ (where R³ is an acid-dissociable group), and k2 is a number ranging from 1 to 3).

Examples of the monovalent unsaturated hydrocarbon group having 2 to 6 carbon atoms include vinyl groups, allyl groups, 1-butenyl groups, 1-pentenyl groups, and 1-hexenyl groups, with vinyl groups and allyl groups being preferred. The acid-dissociable group R³ refers to a group that readily decomposes in the presence of a dilute acid, such as acetic acid or formic acid, to generate a hydroxyl group. R³ is a linear or branched hydrocarbon group, a —(C═O)—R⁷ group (R⁷ is a linear monovalent hydrocarbon group), a —R⁸OR⁹ group (R⁸ is a linear or branched divalent hydrocarbon group. R⁹ is a linear monovalent hydrocarbon group), and trialkylsilyl groups are well known. Specific examples include tertiary butyl groups, acetyl groups, methoxymethyl groups, ethoxymethyl groups, ethoxyethyl groups, and trimethylsilyl groups, with tertiary butyl groups and trimethylsilyl groups being recommended groups.

There are no particular limitations on the conditions for the hydrosilylation reaction, but the reaction is commonly carried out in the presence or absence of an organic solvent, as a diluent, at a reaction temperature of room temperature to about 150° C. while stirring for 0.5 to 10 hours. In this case, use of a catalyst is recommended in order to accelerate the reaction. Examples of the catalyst include platinum-based catalysts, rhodium-based catalysts, palladium-based catalysts, nickel-based catalysts, iridium-based catalysts, ruthenium-based catalysts, and iron-based catalysts, but platinum-based catalysts are preferable. Examples of platinum-based catalysts include platinum-based compounds such as platinum fine powder, platinum black, platinum-supported silica fine powder, platinum-supported activated carbon, chloroplatinic acid, an alcohol solution of chloroplatinic acid, platinum olefin complexes, and platinum alkenylsiloxane complexes, but platinum alkenylsiloxane complexes are particularly preferable. Examples of alkenylsiloxanes include: 1,3-divinyl-1,1,3,3-tetramethyldisiloxane; 1,3,5,7-tetramethyl-1,3,5,7-tetravinylcyclotetrasiloxane; alkenyl siloxanes obtained by substituting a portion of the methyl groups of the alkenylsiloxanes with an ethyl group, a phenyl group, or the like; and alkenylsiloxanes obtained by substituting a portion of the vinyl groups of these alkenylsiloxanes with an allyl group, a hexenyl group, or the like. In particular, 1,3-divinyl-1,1,3,3-tetramethyldisiloxane is preferred because a platinum-alkenylsiloxane complex containing this compound will have good stability. Furthermore, the stability of the platinum-alkenylsiloxane complex can be improved. Therefore, a compound selected from organosiloxane oligomers is preferably added to the complex, such as 1,3-divinyl-1,1,3,3-tetramethyldisiloxane, 1,3-diallyl-1,1,3,3-tetramethyldisiloxane, 1,3-divinyl-1,3-dimethyl-1,3-diphenyldisiloxane, 1,3-divinyl-1,1,3,3-tetraphenyldisiloxane, and 1,3,5,7-tetramethyl-1,3,5,7-tetravinylcyclotetrasiloxane, other alkenylsiloxane or dimethylsiloxane oligomers, but alkenylsiloxane is particularly preferably added to the platinum complex.

The amount of the catalyst included will vary depending on the structure of the catalyst and the alkenyl compound and silicon-bonded hydrogen atom-containing organopolysiloxane to be reacted, but will usually be an amount such that the metal atoms in the catalyst are within a range of 0.01 to 100 ppm by mass, based on the total amount of reactive groups excluding the solvent. From the perspective of good reaction rate and suppression of coloration, use of a platinum alkenylsiloxane complex is particularly preferable and the platinum content is adjusted to an amount preferably within the range of 1.0 to 20 ppm. If the amount of catalyst added is too small, the hydrosilylation reaction rate will be slow, but an excessive amount will cause discoloration and will be uneconomical.

Once completion of the hydrosilylation reaction has been confirmed, the product can be filtered, if necessary, and the organic solvent used can be distilled off to isolate the target branched organopolysiloxane. A solvent exchange step can be used in order to disperse the polymer in an organic solvent different from the one used.

### [Step (II)]

The method for producing a phenolic hydroxyl group-containing branched organopolysiloxane of the present invention preferably includes a step (step (II)) of reacting an acidic compound with the branched organopolysiloxane obtained in the above step (I) and having a functional group expressed by the following formula (34) in the molecule. At least a portion of the groups Z on the aromatic ring is converted to hydroxyl groups (X), and the functional group expressed by formula (34) is converted to group M¹ expressed by the formula (21).

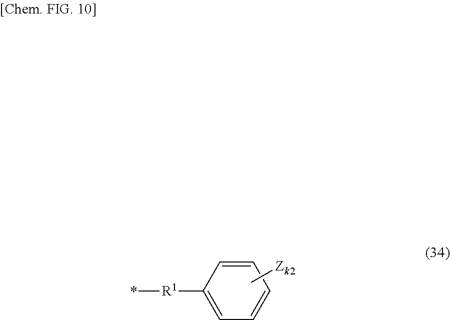

(In the formula, R¹ is a divalent hydrocarbon group having 2 to 6 carbon atoms, Z is the same group as defined above, k2 is a number in a range of 1 to 3, and * is a bonding site to a silicon atom on the organopolysiloxane)

Examples of the acidic compound that can be used here include organic acids such as acetic acid, formic acid, citric acid, paratoluenesulfonic acid, and the like, and inorganic acids such as dilute hydrochloric acid, dilute nitric acid, and the like. In either case, use of more than a stoichiometric amount of water is preferable.

The reaction conditions are not particularly limited, but can be adjusted depending on the structures of the branched organopolysiloxane and acidic compound used. Specifically, the reaction is generally carried out for 1 to 10 hours at a reaction temperature of room temperature to about 100° C. in the presence or absence of an organic solvent that serves to mix the reaction materials and water.

After confirming that the desired reaction has been completed, the product can be subjected to removal of volatile components, followed by steps of neutralization with a basic compound and washing to obtain the desired phenolic hydroxyl group-containing branched organopolysiloxane. The basic compound used here may be an inorganic base such as sodium hydrogen carbonate, an organic base such as ammonia, or a basic solid neutralizing agent. If a solid neutralizing agent is used, a filtration step is required.

Step (II) introduces group M¹ expressed by the following formula (21):

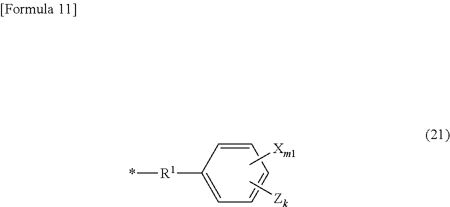

(wherein R¹ is a divalent hydrocarbon group having 2 to 6 carbon atoms, X is a hydroxyl group, Z is a monovalent group represented by —OR³ (wherein R³ is an acid-dissociable group), m1 is a number ranging from 1 to 3, k is a number ranging from 0 to 3, and * is a bonding site to a silicon atom on the organopolysiloxane).

R¹ is a linear or branched divalent hydrocarbon group having 2 to 6 carbon atoms, and is a linking group for the functional group M¹ expressed by formula (21) and the functional group M² expressed by formula (22). Specifically, examples of R¹ include methylene groups, ethylene groups, methylmethylene groups, propylene groups, methylethylene groups, butylene groups, and hexylene groups, but ethylene groups, methylmethylene groups, and propylene groups are preferable.

The substituent Z on the aromatic ring in the functional group M¹ expressed by formula (21) and the functional group M² expressed by formula (22), or the functional group Z in formula (4) is a monovalent group expressed by —OR³ (wherein R³ is an acid-dissociable group) and generates a hydroxyl group in the presence of a dilute acid. In other words, Z is a hydroxyl group protected by an acid-dissociable group R³.

Herein, R³ is an acid-dissociable group, which is easily decomposed in the presence of a dilute acid, such as acetic acid or formic acid, to generate a hydroxyl group from the functional group Z. Specifically, R³ is a linear or branched hydrocarbon group, a —(C═O)—R³¹ group (R³¹ is a linear monovalent hydrocarbon group), or a —R³²OR³³ group (R³² is a linear or branched divalent hydrocarbon group, and R³³ may be a linear monovalent hydrocarbon group), or a trialkylsilyl group. More specifically, examples include tert-butyl groups, acetyl groups, methoxymethyl groups, ethoxymethyl groups, ethoxyethyl groups, and trimethylsilyl groups. Of these, tert-butyl groups and trimethylsilyl groups are preferable.

m1 represents the number of hydroxyl groups (—X) on the aromatic ring in the functional group M¹ expressed by formula (21), and is a number ranging from 1 to 3, with 1 or 2 being preferable.

k represents the number of hydroxyl groups (—Z) protected by the acid-dissociable group R³ in the functional group M¹ expressed by formula (21) and the functional group M² expressed by formula (22), and is a number ranging from 0 to 3, preferably 0 or 1, and more preferably 0. In other words, the functional group Z is an optional functional group in the branched organopolysiloxane of the present invention, and is preferably not contained in the molecule. This can be achieved in step (II) by converting all functional groups Z on the functional group expressed by formula (34) to hydroxyl groups (X) by reacting with an acidic substance.

### [Step (III)]

The phenolic hydroxyl group-containing branched organopolysiloxane according to the present invention may further optionally have a carboxylic acid-containing organic group, which is group M². The carboxylic acid-containing organic group is preferably obtained by step (III) following the above step (II), in which the branched organopolysiloxane having group M¹ expressed by formula (21) in the molecule obtained in step (II) is reacted with one or more types of acid anhydrides to convert a portion of group M¹ to group M² expressed by formula (22).

An anhydride of a dicarboxylic acid is recommended as the acid anhydride in step (III). Specific examples of the acid anhydride include succinic anhydride, butylsuccinic anhydride, nonylsuccinic anhydride, glutaric anhydride, 3,3-dimethylglutaric anhydride, adipic anhydride, phthalic homophthalic anhydride, anhydride, 4,4′-(4,4′-isopropylidenediphenoxy)diphthalic anhydride, tetrachlorophthalic anhydride, 3-nitrophthalic anhydride, 4-methylphthalic anhydride, 4-bromophthalic anhydride, 4,4′-oxydiphthalic anhydride, 3,3′,4,4′-benzophenonetetracarboxylic anhydride, cis-4-cyclohexene-1,2-dicarboxylic anhydride, trimellitic anhydride, and 4,4′-bisphthalic anhydride, but succinic anhydride, glutaric anhydride, phthalic anhydride, and homophthalic anhydride are preferably used.

The reaction conditions are not particularly limited, but can be adjusted depending on the structure of the branched organopolysiloxane having group M¹ and the acid anhydride obtained in step (II). Specifically, the reaction is generally carried out for 0.5 to 10 hours at a reaction temperature of room temperature to about 100° C. in the presence or absence of an organic solvent that serves to mix the reaction materials. The reaction proceeds by heating the base mixture, and a catalyst may be used to accelerate the reaction. Effective catalysts include basic compounds, such as triethylamine, pyridine, N,N-dimethylaniline, tetramethylguanidine, 1,8-diazabicycloundecene, 1,5-diazabicyclononene, and the like. The catalyst can be used in an amount of 0.1 to 3.0% by mass, based on the total amount of the base mixture.

Once completion of the desired reaction has been confirmed, the product can be subjected to steps of neutralization with a basic compound and washing to give the desired phenolic hydroxyl group and carboxyl group-containing curable branched organopolysiloxane. The basic compound used here can be an inorganic base such as sodium hydrogen carbonate, an organic base such as ammonia, or a basic solid neutralizing agent. If a solid neutralizing agent is used, a filtration step is required.

Substituent Y on the aromatic ring in the functional group M² expressed by formula (22) that was introduced by step (III) is a carboxylic acid-containing organic group expressed by —Wₚ—R²_{q}—CO₂H. In the formula, W on group Y is a divalent linking group containing a heteroatom, and is a group selected from ester groups O(C═O), amide groups NR⁵(C═O) (where R⁵ is a hydrogen atom or a methyl group), and thioester groups S(C═O). An ester group is preferably used in the phenolic hydroxyl group-containing branched organopolysiloxane of the present invention.

The linking group R² on group Y may be a linear, branched, or cyclic divalent hydrocarbon group with 2 to 12 carbon atoms containing an oxygen atom or a sulfur atom; a sulfur-containing linear, branched, or cyclic divalent hydrocarbon group; or an oxygen-containing linear, branched, or cyclic divalent hydrocarbon group. More specifically, the divalent group is exemplified by the following structural formula (7). Of these, the divalent linking groups represented by 6a, 6b, 6c, 6d, 6e, 6i, 6k, 6m, 6p, 6q, 6q, and 6s can be preferably used.

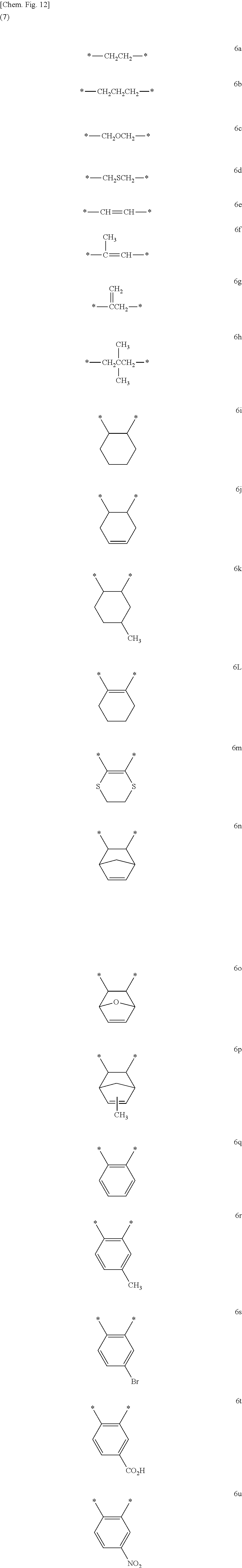

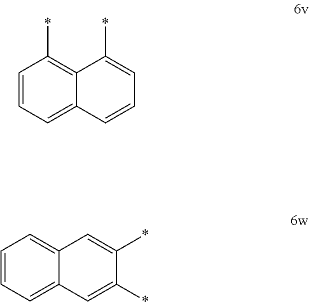 [SMILES: *c1cccc2cccc(*)c12 ; *c1cc2ccccc2cc1*]

(In the formula, * indicates the binding site.)

In group Y, p is either 0 or 1, but is preferably 1. Furthermore, q is either 0 or 1, but is preferably 1.

m2 represents the number of hydroxyl groups (—X) on the aromatic ring in the functional group M² expressed by formula (22) and is either 0 or 1, but is preferably 0. Furthermore, n represents the number of the carboxylic acid-containing organic group, which is the substituent Y, on the aromatic ring in functional group M², and is a number in a range of 1 to 3, but is preferably 1. Incidentally, k is as described above.

From the perspective of achieving favorable curability using a high energy beam, if the phenolic hydroxyl group-containing branched organopolysiloxane of the present invention has a functional group M², the sum of the phenolic hydroxyl groups (X) in functional group M¹ and functional group M² in the entire molecule is greater than the sum of the carboxylic acid-containing organic groups (Y) in the functional group M². In other words, the value of [sum of the mass amount of hydroxyl groups (X) in groups M¹ and M² in the molecule]/[sum of mass amount of the carboxylic acid-containing hydrophilic groups (Y) in group M² in the molecule] is preferably 1 or more.

### [Phenolic Hydroxyl Group-Containing Branched Organopolysiloxane]

The phenolic hydroxyl group-containing branched organopolysiloxane produced in the present invention has a structure expressed by the following average unit formula (1). At least one of all A's is M¹, and optionally, particularly when produced using the aforementioned step (III), at least one of all A's is M¹ and at least one is M², and the resulting branched organopolysiloxane may be, and is preferably, a co-modified branched organopolysiloxane having both a phenolic hydroxyl group-containing organic group and a carboxylic acid-containing organic group.

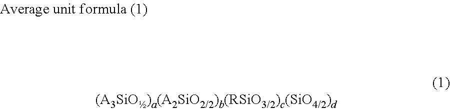

In the formula, R represents the same groups as described above, each A independently represents one or more type selected from:
groups similar to R described above,
M¹ expressed by formula (21)

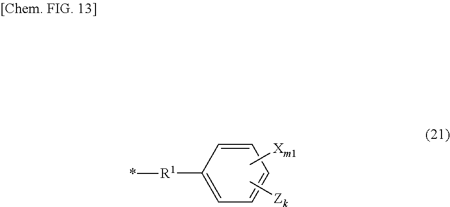

(wherein R¹ is a divalent hydrocarbon group having 2 to 6 carbon atoms, X is a hydroxyl group, Z is a monovalent group represented by —OR³ (wherein R³ is an acid-dissociable group), m1 is a number ranging from 1 to 3, k is a number ranging from 0 to 3, and * is a bonding site to a silicon atom on the organopolysiloxane);
M² expressed by the following formula (22)

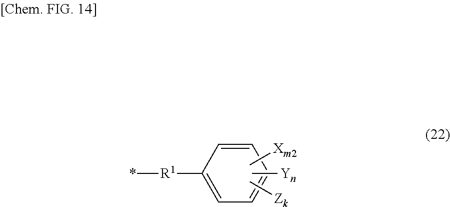

(In the formula, R¹, X, and Z are the same groups as described above,
Y is a monovalent hydrophilic group expressed by —Wₚ—R²_{q}—CO₂H (where W represents a divalent linking group selected from O(C═O), NR⁵(C═O), and S(C═O) groups, p is 0 or 1,
q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group),
m2 is 0 or 1, n is a number in a range of 1 to 3, k is a number in a range of 0 to 3, and * is a silicon atom-bonding site on the organopolysiloxane);
group J expressed by the following formula (3):

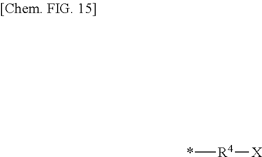

(in the formula, R⁴ represents a divalent hydrocarbon group with 2 to 6 carbon atoms, and
X represents the aforementioned groups); and
group L expressed by the following formula (4):

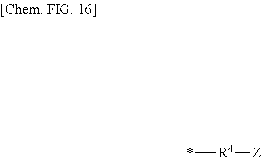

(in the formula, R⁴ and Z represent the same groups as described above); and
at least one of all A is M¹, and a, b, c, and d are numbers that satisfy the aforementioned conditions.

Functional group J in the phenolic hydroxyl group-containing branched organopolysiloxane of the present invention is a group containing an alcoholic hydroxyl group and is expressed by the aforementioned formula (3). Group X in formula (3) is a hydroxyl group, as defined above. The linking group R⁴ is a linear or branched divalent hydrocarbon group having 2 to 6 carbon atoms. Specific examples include methylene groups, ethylene groups, methylmethylene groups, propylene groups, methylethylene groups, butylene groups, and hexylene groups. Of these, ethylene groups, methylmethylene groups, and propylene groups are preferable. Functional group J is an optional component of the phenolic hydroxyl group-containing branched organopolysiloxane according to the present invention, and is not required to be included in the molecule.

Functional group L in the phenolic hydroxyl group-containing branched organopolysiloxane of the present invention is a group containing a hydroxyl group (—Z) protected by an acid-dissociable group R³ via a linking group R⁴, as expressed by the aforementioned formula (4). Herein, R⁴ and Z in formula (4) are the same groups as defined above. Functional group L is an optional component of the phenolic hydroxyl group-containing branched organopolysiloxane of the present invention, is not required, and preferably is not included in the molecule.

### [Optional Steps]

The above functional group J or functional group L can be introduced into the phenolic hydroxyl group-containing branched organopolysiloxane of the present invention by, for example, subjecting the silicon atom-bonded hydrogen atom-containing branched organopolysiloxane expressed by the aforementioned average unit formula (1′) to a hydrosilylation reaction in step (I) or the like with an unsaturated hydrocarbon group-containing compound expressed by the structural formulas (3′) or (4′).

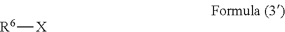

(In the formula, R⁶ is synonymous with the groups described above)

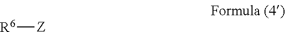

(In the formula, R⁶ and Z are synonymous with the groups described above)

Furthermore, there are no particular limitations on the molecular weight of the phenolic hydroxyl group-containing branched organopolysiloxane, but when considering the coatability, high energy beam curability, alkali solubility, and mechanical strength properties of the coated film, the weight average molecular weight, calculated on the basis of a polystyrene standard, as measured by gel permeation chromatography is preferably 1000 to 3000, more preferably 1500 to 3000, and particularly preferably 1500 to 2500. From the perspective of maintaining excellent alkali solubility, the molecular weight distribution is preferably 1.5 or less, and particularly preferably 1.4 or less.

### [Use of Organic Solvents]

In the production method of the present invention for producing a phenolic hydroxyl group-containing branched organopolysiloxane, the use of an organic solvent is optional, but an appropriate amount of an appropriate organic solvent is preferably used by taking into consideration the miscibility of the reaction base and the dispersibility of the optional catalyst compound.

Suitable examples of the organic solvent include: (poly)alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, propylene glycol monoethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, and the like; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate (PGMEA), propylene glycol monoethyl ether acetate, and the like; other ethers such as diethylene glycol dimethyl ether, diethylene glycol methyl ethyl ether, and diethylene glycol diethyl ether; ketones such as methyl ethyl ketone, methyl isobutyl ketone, cyclohexanone, 2-heptanone, 3-heptanone, 4-heptanone, 5-methyl-3-heptanone, 2,4-dimethyl-3-pentanone, 2,6-dimethyl-4-heptanone, and the like; alkyl lactates such as methyl 2-hydroxypropionate, ethyl 2-hydroxypropionate, and the like; other esters such as ethyl 2-hydroxy-2-methylpropionate, methyl-3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxy butylacetate, 3-methyl-3-methoxybutylacetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and the like; aromatic hydrocarbons such as toluene, xylene, mesitylene, cumene, propylbenzene, diethylbenzene, 1,3-diisopropylbenzene, and the like; and aromatic ethers such as anisole, phenethol, 2-methoxytoluene, 3-methoxytoluene, 4-methoxytoluene, 3,4-dimethoxytoluene, 1,4-bis(methoxymethyl)benzene, and the like. These may be used alone or as a mixed solvent containing two or more types.

There is no limitation on the amount of organic solvent used, but use of an amount that results in a base concentration in a range of 5 to 90% by mass is recommended, preferably 10 to 80% by mass.

### [Method of Producing Curable Composition]

The phenolic hydroxyl group-containing branched organopolysiloxane obtained by the production method of the present invention contains at least one phenolic hydroxyl group-containing organic group expressed by M¹ in the molecule, and has curing reactivity. The curing reaction mechanism is not particularly limited so long as the curing reaction involves the phenolic hydroxyl group, and examples include one or more reactions selected from condensation reactions, radical polymerization reactions, peroxide curing reactions, and high energy beam (for example, ultraviolet ray) curing reactions, and thus a curable composition containing the phenolic hydroxyl group-containing branched organopolysiloxane of the present invention can be designed. In other words, a method for producing a curable composition, which includes the production method of the present invention (for example, the above steps (I), (II) and optionally step (III), and the like) can be used.

### [Method for Producing High Energy Beam Curable Composition]

The phenolic hydroxyl group-containing branched organopolysiloxane of the present invention has excellent alkali solubility and high-energy beam curability, and therefore is particularly preferably used in high energy beam-curable compositions, and a method for producing a high energy beam-curable composition including the production method of the present invention can be provided. More specifically, the high energy beam-curable composition of the present invention contains at least the phenolic hydroxyl group-containing branched organopolysiloxane of the present invention and a photoacid generating agent necessary for curing, and may optionally contain other components.

More specifically, the high energy beam-curable composition of the present invention contains the following four components. Component (A) is the main component of the present invention as described. Note that, the crosslinking agent (C) is an optional component that may be added as necessary when component (A) does not have a carboxylic acid-containing organic group. Furthermore, the amount of the organic solvent used can be appropriately selected for the purpose of adjusting the coatability and other properties of the composition.
(A) the aforementioned phenolic hydroxyl group-containing branched organopolysiloxane;
(B) a photoacid generating agent in an amount of 0.1 to 20 parts by mass per 100 parts by mass of component (A);
(C) Crosslinking agent in an amount of 0 to 30 parts by mass per 100 parts by mass of component (A);
and
(D) an organic solvent.

Components (B) and (C) can be a known photoacid generating agent, crosslinking agent, and the like, without particular limitation, and component (D) can be any known organic solvent in addition to the aforementioned organic solvents, without particular limitation. The curable composition according to the present invention (particularly the high energy beam-curable composition) can be obtained by mechanically mixing component (A) obtained by the production method of the present invention with other components.

The present invention is further described below on the basis of Examples, but the present invention is not limited to the Examples below.

### EXAMPLES

The method for producing the curable branched organopolysiloxane of the present invention will now be described in more detail with reference to examples.

### [Appearance of Curable Composition and Cured Product]

The curable composition and cured product were visually observed to determine the appearance.

### [Alkali Solubility of Curable Branched Organopolysiloxane]

A 20 mass % PGMEA solution of each curable branched organopolysiloxane was spin-coated onto an optical glass substrate to a thickness of 0.3 to 0.5 μm, and heated (pre-baked) at 90° C. for 1.5 minutes using a hot plate to form a coating film. The film was then developed in a 2.38% aqueous solution of tetramethylammonium hydroxide (TMAH) at 25° C. for 1 minute, followed by an immersion water wash in a water bath at room temperature (25° C.). The water wash time was 15 seconds. After rinsing and drying to remove water, the glass substrate was visually observed to determine the solubility (developability) in alkaline solutions using the following criteria.
A: Completely dissolved: Paint film is completely removed
B: Almost dissolved: A tiny amount of paint residue (scum) is observed
C: Partially dissolved: Large amount of scum (more than 20% of coating area) observed
D: Insoluble

### [High Energy Beam Curability of Curable Composition]

A PGMEA solution of each curable composition (curable branched organopolysiloxane concentration: 20 mass %) was used to form a coating of the curable composition by the same method as above. This coating film was irradiated with a high energy beam from a high pressure mercury lamp (light amount at 254 nm: 2000 mJ/cm²) to obtain a cured coating film. The high energy beam curability was determined using the following criteria.
A: Cured coating is insoluble in the TMAH dissolution test
B: Only the edge portions of the cured coating (less than 5% of the total area of the cured coating) are dissolved in the TMAH dissolution test
C: Cured coating is completely or almost completely dissolved in the TMAH dissolution test.

### [Example 1] Synthesis of Phenolic Hydroxyl Group-Containing Curable Branched Organopolysiloxane (A-1)

A 200 mL three-neck flask equipped with a thermometer and a nitrogen inlet tube was charged with 40.1 g of dimethylsiloxy-capped phenylsilsesquioxane (silicon-bonded hydrogen content: 0.66 mass %), 10 g of toluene, 46.2 g of t-butoxystyrene, and a platinum(0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 100° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched phenylsilsesquioxane in which silicon-bonded hydrogen atoms were replaced with t-butoxyphenylethyl groups. A 200 mL three-neck flask equipped with a thermometer and a nitrogen inlet tube was charged with 84.46 g of a branched phenylsilsesquioxane substituted with t-butoxyphenylethyl groups and 157 g of a 90 mass % aqueous formic acid solution, and then heated at 100° C. for 5 hours, after which completion of the reaction was confirmed. Volatile components were removed, and the residue was diluted with 100 ml of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

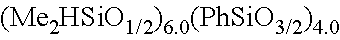

Here, Me represents a methyl group, Ph represents a phenyl group, and A represents a (CH₂)₂C₆H₄OH group.

Gel permeation chromatogram analysis showed that the weight average molecular weight (Mw) and polydispersity (PDI) of (A-1) were 1700 and 1.36, respectively.

### [Example 2] Synthesis of Phenolic Hydroxyl Group-Containing Curable Branched Organopolysiloxane (A-2)

A 200 mL three-neck flask equipped with a thermometer and a nitrogen inlet tube was charged with 32.0 g of dimethylsiloxy-capped silica (silicon-bonded hydrogen content: 0.97 mass %), 54.3 g of t-butoxystyrene, and a platinum(0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 120° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched silica in which silicon-bonded hydrogen atoms were replaced with t-butoxyphenylethyl groups.

A 200 mL three-neck flask equipped with a thermometer and a nitrogen inlet tube was charged with 82.8 g of a branched silica substituted with t-butoxyphenylethyl groups and 157 g of a 90 mass % aqueous formic acid solution, and then heated at 100° C. for 4 hours, after which completion of the reaction was confirmed. Volatile components were removed, and the residue was diluted with 100 mL of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

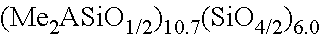

Here, Me represents a methyl group, and A represents a (CH₂)₂C₆H₄OH group.

Gel permeation chromatogram analysis showed that the weight average molecular weight (Mw) and polydispersity (PDI) of (A-2) were 2400 and 1.14, respectively.

### [Example 3] Synthesis of Phenolic Hydroxyl Group-Containing Curable Branched Organopolysiloxane (A-3)

A 200 mL three-neck flask equipped with a thermometer and a nitrogen inlet tube was charged with 13.2 g of dimethylsiloxy-capped silica (silicon-bonded hydrogen content: 0.97 mass %), 36.7 g of O,O-bistrimethoxysilyl-4-vinylcatechol, and a platinum(0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 120° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched silica in which silicon-bonded hydrogen atoms were replaced with 3,4-bistrimethylsiloxyphenylethyl groups.

A 200 mL three-neck flask equipped with a thermometer and a nitrogen inlet tube was charged with 48.0 g of branched silica substituted with 3,4-bistrimethylsiloxyphenylethyl groups, 100 mL of tetrahydrofuran, 5 g of a 90 mass % aqueous formic acid solution, and 10.0 g of purified water, and the mixture was heated at 60° C. for 90 minutes, after which the completion of the reaction was confirmed. The volatile components were removed and the mixture was diluted with 100 mL of PGMEA to obtain a PGMEA solution of the product. Analysis by ¹³C and ²⁹Si NMR spectroscopy confirmed the product to be a branched organopolysiloxane having the following average composition:

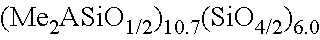

Here, Me represents a methyl group, and A represents a (CH₂)₂C₆H₃(OH)₂ group.

Gel permeation chromatogram analysis showed that the weight average molecular weight (Mw) and polydispersity (PDI) of (A-3) were 2400 and 1.04, respectively.

### [Example 4] Synthesis of Branched Organopolysiloxane Containing a Group Containing a Phenolic Hydroxyl Group and a Carboxyl Group (A-4)

A 200 mL three-neck flask equipped with a thermometer and a nitrogen inlet tube was charged with 58.6 g of the product obtained in Example 1, 90 g of PGMEA, 7.2 g of succinic anhydride, and 0.12 g of tetramethylguanidine, and then heated at 90° C. for 4 hours, after which completion of the reaction was confirmed. After cooling to room temperature, 3 g of Kyoward 700PL was added to neutralize the reaction system. A white solid was filtered out to give a PGMEA solution of the product. Analysis by ¹³C and ²⁹Si NMR spectroscopy confirmed the product to be a branched organopolysiloxane having the following average composition:

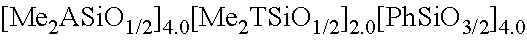

Here, Me represents a methyl group, Ph represents a phenyl group, A represents a (CH₂)₂C₆H₄OH group, and B represents a (CH₂)₂C₆H₄O(C═O)(CH₂)₂CO₂H group.

Gel permeation chromatogram analysis showed that the weight average molecular weight (Mw) and polydispersity (PDI) of (A-4) were 1900 and 1.36, respectively.

### [Example 5] Synthesis of Branched Organopolysiloxane Containing a Group Containing a Phenolic Hydroxyl Group and a Carboxyl Group (A-5)

A 200 mL three-neck flask equipped with a thermometer and a nitrogen inlet tube was charged with 41.6 g of the product obtained in Example 2, 178 g of PGMEA, 1.7 g of succinic anhydride, and 0.03 g of tetramethylguanidine, and then heated at 90° C. for 4 hours, after which completion of the reaction was confirmed. After cooling to room temperature, 1.5 g of Kyoward 700PL was added to neutralize the reaction system. A white solid was filtered out to give a PGMEA solution of the product. Analysis by ¹³C and ²⁹Si NMR spectroscopy confirmed the product to be a branched organopolysiloxane having the following average composition:

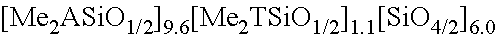

Here, Me represents a methyl group, A represents a (CH₂)₂C₆H₄OH group, and T represents a (CH₂)₂C₆H₄O(C═O)(CH₂)₂CO₂H group.

Gel permeation chromatogram analysis showed that the weight average molecular weight (Mw) and polydispersity (PDI) of (A-5) were 2400 and 1.36, respectively.

### [Evaluation Examples 1-1 to 1-5, Comparative Evaluation Examples 1-1 to 1-4] Alkali Solubility of Curable Branched Organopolysiloxane

The alkali solubility was evaluated using a 20 mass % PGMEA solution of the branched organopolysiloxane shown below, and the results are compiled in Table 1.
A-1: Phenolic hydroxyl group-containing branched organopolysiloxane obtained in Synthesis Example 1
A-2: Phenolic hydroxyl group-containing branched organopolysiloxane obtained in Synthesis Example 2
A-3: Phenolic hydroxyl group-containing branched organopolysiloxane obtained in Synthesis Example 3
A-4: Branched organopolysiloxane having a phenolic hydroxyl group and a carboxyl group, obtained in Synthesis Example 4
A-5: Branched organopolysiloxane having a phenolic hydroxyl group and a carboxyl group, obtained in Synthesis Example 5
P-1: Branched organopolysiloxane which is solid at room temperature and has an average composition ([Me₂HSiO_{1/2}]_{5.0}[PhSiO_{3/2}]_{15.0}) similar to the dimethylsiloxy group-capped phenylsilsesquioxane used in Synthesis Example 1
P-2: Branched organopolysiloxane which is liquid at room temperature and has an average composition ([Me₂HSiO_{1/2}]_{6.0}[PhSiO_{3/2}]_{4.0}) similar to the dimethylsiloxy group-capped phenylsilsesquioxane used in Synthesis Example 1
P-3: Branched organopolysiloxane which is solid at room temperature and has an average composition ([Me₂HSiO_{1/2}]_{29.0}[SiO_{4/2}]_{36.0}) similar to the dimethylsiloxy group-capped silica used in Synthesis Example 2
P-4: Branched organopolysiloxane which is liquid at room temperature and has an average composition ([Me₂HSiO_{1/2}]_{10.7}[SiO_{4/2}]_{6.0}) similar to the dimethylsiloxy group-capped silica used in Synthesis Example 2

TABLE 1

| | Evaluation | Evaluation | Evaluation | Evaluation | Evaluation | Comparative | Comparative | Comparative | Comparative |
|---|---|---|---|---|---|---|---|---|---|
| | Example | Example | Example | Example | Example | evaluation | evaluation | evaluation | evaluation |
| | 1-1 | 1-2 | 1-3 | 1-4 | 1-5 | example 1-1 | example 1-2 | example 1-3 | example 1-4 |
| Component | A-1 | A-2 | A-3 | A-4 | A-5 | P-1 | P-2 | P-3 | P-4 |
| (branched | | | | | | | | | |
| organopoly- | | | | | | | | | |
| siloxane) | | | | | | | | | |
| a/(b + c + d) in | 1.50 | 1.78 | 1.78 | 1.50 | 1.78 | 0.33 | 1.50 | 0.82 | 1.78 |
| formula (1) | | | | | | | | | |
| Alkali solubility | C | B | A | A | A | D | *1 | *2 | *1 |
| evaluation | | | | | | | | | |

*1: Evaluation was impossible because a solid coating film was not formed.
*2: Evaluation was impossible because a uniform coating film was not formed.

### [Evaluation Examples 2 to 4, and Comparative Evaluation Example 2] Evaluation of Curable Branched Organopolysiloxane Composition

The following PGMEA solutions of a branched organopolysiloxane, crosslinking agent, and curing catalyst were mixed in the compositions shown in Table 2 (parts by mass; branched organopolysiloxane is calculated on the basis of solid content), and the mixtures were filtered through a membrane filter having a pore size of 0.2 μm to prepare high energy beam-curable compositions.

### Curable Branched Organopolysiloxanes:

A-3: Curable branched organopolysiloxane obtained in Example 3
A-5: Curable branched organopolysiloxane obtained in Example 5
P-1: Branched organopolysiloxane which is solid at room temperature and has the configuration of ([Me₂HSiO_{1/2}]_{5.0}[PhSiO_{3/2}]_{15.0})

### Photoacid Generating Agent:

B-1: Tri-p-tolylsulfonium trifluoromethanesulfonate (TS-01; manufactured by Sanwa Chemical Co., Ltd.)

### Curing Agent:

C-1: Tetrakis methoxymethyl glycoluril (Nikalac MX-270; manufactured by Sanwa Chemical Co., Ltd.)

TABLE 2

| | | | | Comparative |
|---|---|---|---|---|
| | Evaluation | Evaluation | Evaluation | evaluation |
| Component | Example 2 | Example 3 | Example 4 | example 2 |
| (A-3; as solid content) | 100 | | | |
| (A-5; as solid content) | | 100 | 100 | |
| (P-1) | | | | 100 |
| (B-1) | 2 | 2 | 2 | 2 |
| (C-1) | 30 | 10 | | 30 |
| Total | 132 | 112 | 102 | 132 |
| Appearance of | Clear | Clear | Clear | Clear |
| curable composition | | | | |
| High energy | A | A | A | C |
| beam curability | | | | |
| Appearance of | Clear | Clear | Clear | Uncured |
| cured product | | | | |
| Alkali solubility | A | A | A | D |

### SUMMARY

As shown in Table 1, the coating films formed from the phenolic hydroxyl group-containing branched organopolysiloxanes (including co-modified types) obtained by the production method of the present invention exhibited alkali solubility sufficient for practical use, and some (A-2 to A-5) exhibited particularly excellent alkali solubility. Note that the curable branched organopolysiloxanes according to the comparative examples all had poor alkali solubility or were insoluble in alkali, and could not be used for development with an aqueous alkaline solution.

Furthermore, as shown in Table 2, the high-energy beam-curable organopolysiloxane compositions (Evaluation Examples 2 to 4) using the phenolic hydroxyl group-containing branched organopolysiloxane (including the co-modified type) obtained by the production method of the present invention had favorable high energy beam curability. Furthermore, the cured coating film formed by irradiation with a high energy beam was transparent and exhibited sufficiently high coating toughness. On the other hand, the branched polyorganosiloxane that did not have a phenolic hydroxyl group (Comparative Evaluation Example 2) had poor alkali solubility and also had did not have curing properties, so use would be difficult in the photopatterning process.

### INDUSTRIAL APPLICABILITY

The phenolic hydroxyl group-containing branched organopolysiloxane obtained by the production method of the present invention and the curable composition containing this compound as a main component, in particular, the high energy beam-curable composition, have excellent high energy beam curability while also having excellent alkali solubility, and therefore have the advantages that pattern formation can be carried out easily and with high precision, particularly when subjected to a development step using an aqueous alkali solution, and the obtained cured film has excellent mechanical strength and transparency. Therefore, the organopolysiloxanes and the like are particularly suitable as materials, especially patterning materials, coating materials, and resist materials for forming insulating layers for touch panels and display devices such as displays, especially flexible displays.

1. A method for producing a phenolic hydroxyl group-containing branched organopolysiloxane, expressed by the following average unit formula (1), the method comprising:
at least a step of performing a hydrosilylation reaction of a silicon atom-bonded hydrogen atom-containing branched organopolysiloxane expressed by average unit formula (1′); 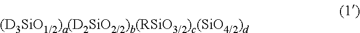
where R is a group selected from hydrogen atoms, unsubstituted or fluorine-substituted monovalent hydrocarbon groups, alkoxy groups, and hydroxyl groups; each D is independently a group similar to R; at least one of all Ds is a hydrogen atom; and a, b, c, and d are numbers that satisfy the following conditions: 0≤a, 0≤b, 0<(a+b), and 0<(c+d);
where average unit formula (1) is: 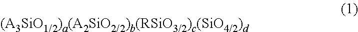
where R represents the same groups as described above;
each A independently represents the same groups as R,
groups M¹ expressed by the following formula (21): 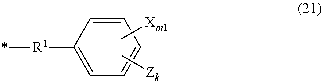
where R¹ is a divalent hydrocarbon group having 2 to 6 carbon atoms, X is a hydroxyl group, Z is a monovalent group expressed by —OR³ where R³ is an acid-dissociable group, m1 is a number in a range of 1 to 3, k is a number in a range of 0 to 3, and * is a silicon atom-bonding site on the organopolysiloxane,
groups M² expressed by the following formula (22): 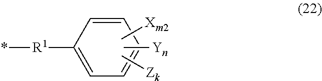
where R¹, X, and Z are the same groups as described above,
Y is a monovalent hydrophilic group expressed by —Wₚ—R²_{q}—CO₂H where W represents a divalent linking group selected from O(C═O), NR⁵(C═O), and S(C═O) groups, p is 0 or 1, q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group,
m2 is 0 or 1, n is a number in a range of 1 to 3, k is a number in a range of 0 to 3, and * is a silicon atom-bonding site on the organopolysiloxane,
groups J expressed by the following formula (3): 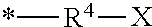
where R⁴ represents a divalent hydrocarbon group with 2 to 6 carbon atoms, and X represents the aforementioned groups; and
groups L expressed by the following formula (4): 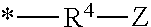
where R⁴ and Z represent the same groups as described above; and
at least one of all A represents M¹, and a, b, c, and d are numbers satisfying the aforementioned conditions.

2. The method for producing a phenolic hydroxyl group-containing branched organopolysiloxane according to claim 1, comprising:
at least step (I) of performing a hydrosilyl reaction between a silicon atom-bonded hydrogen atom-containing branched organopolysiloxane expressed by the above average unit formula (1′) with an unsaturated hydrocarbon group-containing compound expressed by the following formula (33): 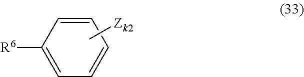
where R⁶ is a monovalent unsaturated hydrocarbon group having 2 to 6 carbon atoms, Z is the same groups as described above, and k2 is a number ranging from 1 to 3.

3. The method for producing a phenolic hydroxyl group-containing branched organopolysiloxane according to claim 2, further comprising:
after the aforementioned step (I), a step (II) where one or more acidic substance is reacted with the product of step (I), a compound expressed by the following formula (34): 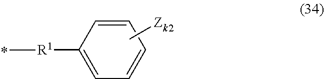
where R¹ is a divalent hydrocarbon group having 2 to 6 carbon atoms, Z is the same group as defined above, k2 is the same number as defined above, and * is a bonding site to a silicon atom on the organopolysiloxane
to convert at least a portion of the groups Z to hydroxyl groups (X), thereby converting the functional group expressed by formula (34) to the group M¹ expressed by formula (21).

4. The method for producing a phenolic hydroxyl group-containing branched organopolysiloxane according to claim 3, further comprising, after step (II), step (III) in which the branched organopolysiloxane having group M¹ expressed by formula (21) in the molecule obtained in step (II) is reacted with one or more types of acid anhydride to convert a portion of group M¹ to group M² expressed by formula (22).

5. The method for producing a phenolic hydroxyl group-containing branched organopolysiloxane according to claim 1, wherein the silicon atom-bonded hydrogen atom-containing branched organopolysiloxane expressed by the average unit formula (1′) has 50 or fewer silicon atoms in the molecule.

6. The method for producing a phenolic hydroxyl group-containing branched organopolysiloxane according to claim 1, wherein the silicon atom-bonded hydrogen atom-containing branched organopolysiloxane expressed by the average unit formula (1′) has a range of 5 to 20 silicon atoms in the molecule.

7. The method for producing a phenolic hydroxyl group-containing branched organopolysiloxane according to claim 1, where in the average unit formula (1′), a is a number of 1 or more.

8. The method for producing the phenolic hydroxyl group-containing branched organopolysiloxane according to claim 1, wherein the silicon atom-bonded hydrogen atom-containing branched organopolysiloxane expressed by the average unit formula (1′) is an organopolysiloxane expressed by the following average unit formula (1-1′) or (1-2′): 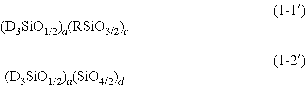
where R and A are the same groups as defined above, and a, c, and d are numbers satisfying the above conditions.
